(19) United States
(12) Patent Application Publication
(10) Pub. No.: US 2009/0212340 A1
(43) Pub. Date: Aug. 27, 2009

(54) FLASH MEMORY DEVICES

(75) Inventors: Chang-Hyun Lee, Gyeongi-do (KR); Young-Woo Park, Seoul (KR); Jung-Dal Choi, Seoul (KR); Chang-Seok Kang, Gyeonggi-do (KR); Jin-Taek Park, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/392,656

(22) Filed: Feb. 25, 2009

(30) Foreign Application Priority Data
Feb. 25, 2008 (KR) 2008-16898

(51) Int. Cl. H01L 29/788

(52) U.S. Cl. 257/315; 257/E29.3

(57) ABSTRACT

A gate electrode line which extends in a second direction crossing a first direction on a substrate including an active region which is defined by a device isolation layer and extends in the first direction and a charge trap layer disposed between the active region and the gate electrode line, wherein a bottom surface of the gate electrode line disposed on the device isolation layer is lower than a top surface of the charge trap layer disposed on the active region and higher than a top surface of the active region.

### CROSS-REFERENCE TO RELATED APPLICATIONS

This U.S. non-provisional patent application claims priority under 35 U.S.C. §119 of Korean Patent Application No. 2008-0016898, filed on Feb. 25, 2008, the entire contents of which are hereby incorporated by reference.

### BACKGROUND

Example embodiments disclosed herein relate to flash memory devices and methods of forming the same, and more particularly, to flashing memory devices including a charge trap layer and methods of forming the same.

Nonvolatile memory devices are semiconductor devices that maintain stored data when a power supply is interrupted. Nonvolatile memory device may be classified into a floating gate type device and a floating trap type device according to a structure of a memory cell.

A memory cell of a floating trap type device may include a gate insulating layer, a charge storage layer, a blocking insulating layer and a gate electrode. A memory cell of a floating trap type device may be programmed by a method of storing a charge in a trap of a charge storage layer. A memory cell of a floating gate type device may include a tunnel insulating layer, a floating gate which is a charge storage layer, a gate dielectric interlayer and a control gate.

Memory cells of a nonvolatile memory device may have a string structure disposed in series. In one string, memory cells are programmed according to a predetermined order. Each of the memory cells is programmed within a range of a predetermined threshold voltage. A first memory cell and a second memory cell adjacent to each other may be sequentially programmed. After a charge is stored in a charge storage layer of a first memory cell and the first memory cell is programmed, a charge is stored in an adjacent charge storage layer of a second memory cell and the second memory cell may be programmed. A first memory cell may be interfered by a charge stored in a charge storage layer of a second memory cell programmed later. A threshold voltage of a first memory cell which is already programmed is increased by an interference phenomenon. As a result, a range of a threshold voltage of a first memory cell may broaden. That is, a distribution of a program of a memory cell may be broadened. Thus, it may be difficult to realize a multi level cell and to control a device.

### SUMMARY

Exemplary embodiments provide a flash memory device. The flash memory device may include a gate electrode line which extends in a second direction crossing a first direction on a substrate including an active region which is defined by a device isolation layer and extends in the first direction and a charge trap layer disposed between the active region and the gate electrode line, wherein a bottom surface of the gate electrode line disposed on the device isolation layer is lower than a top surface of the charge trap layer disposed on the active region and higher than a top surface of the active region.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a top plan view of a flash memory device according to a present invention.

FIG. 2 is a cross-sectional view taken along the line I-I′ of FIG. 1 of a flash memory device according to a first embodiment of the present invention.

FIG. 3 is a cross-sectional view taken along the line I-I′ of FIG. 1 of a flash memory device according to a second embodiment of the present invention.

FIG. 4 is a cross-sectional view taken along the line I-I′ of FIG. 1 showing an active region of a flash memory device according to an embodiment of the present invention.

FIG. 5 is a cross-sectional view taken along the line I-I′ of FIG. 1 showing a comparative example compared with an embodiment of the present invention.

FIGS. 6A and B are graphs illustrating operational characteristics of a comparative example and embodiments according to the present invention, respectively.

FIGS. 7 through 10 are cross-sectional views taken along the line I-I′ of FIG. 1 illustrating a method of forming a flash memory device according to a first embodiment of the present invention.

FIGS. 11 through 16 are cross-sectional views taken along the line I-I′ of FIG. 1 illustrating a method of forming a flash memory device according to a second embodiment of the present invention.

FIG. 17 is a schematic view of a module of a semiconductor device including a flash memory device according to an embodiment of the present invention.

FIG. 18 is a block diagram of a memory system including a flash memory device according to an embodiment of the present invention.

FIG. 19 is a block diagram of an electronic device including a flash memory device according to embodiments of the present invention.

### DETAILED DESCRIPTION OF PREFERRED EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,”“bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

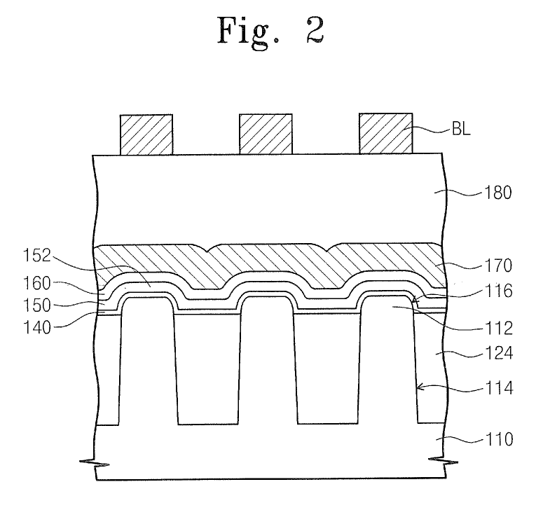

It will be understood that when a first element is described as being, for example, directly above a second element, the portion of the first element is located within the lateral boundaries of the second element. For example, as shown in FIG. 2, a bottom surface of the gate electrode line that is disposed directly above the device isolation layer is lower than a top surface of the charge trap layer that is disposed directly above the active region and is higher than a top surface of the active region

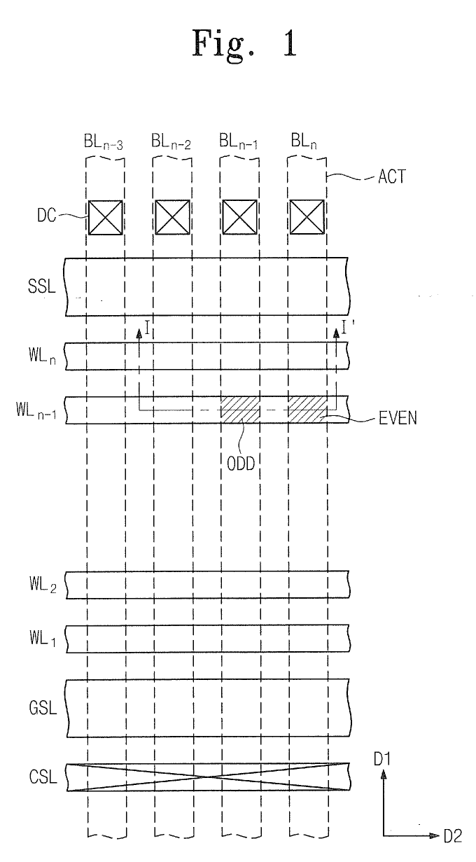

Referring to FIGS. 1, 2 and 4, a flash memory device according to a first embodiment of the present invention will be described.

A substrate 110 is provided. The substrate 110 may be a silicon wafer or a silicon on insulator (SOI) substrate. A device isolation layer 124 may be disposed in a trench 114 formed in the substrate 110. An active region (ACT) 112 extending in a first direction (DI) may be defined by the device isolation layer 124. A top surface of the device isolation layer 124 may be lower than a top surface of the active region 112. The active region 112 exposed by a difference between a height of the device isolation layer 124 and a height of the active region 112 may have a rounded corner 116. For instance, the active region 112 may have a larger radius of curvature at center 117 than at corner 116 (FIG. 4). A plurality of word lines (WL₁, WL₂, . . . WLₙ₋₁, WLₙ) may extend in a second direction (D2) crossing the first direction (D1). A string selection line (SSL), a ground selection line (GSL) and a common source line (CSL) may be disposed in parallel to the word lines (WL₁, WL₂, . . . WLₙ₋₁, WLₙ). The string selection line (SSL) may be disposed to be adjacent to the n'th word line (WLₙ). The ground selection line (GSL) and the common source line (CSL) may be sequentially disposed to be adjacent to the first word line (WL₁).

Each of the word lines (WL₁, WL₂, . . . WLₙ₋₁, WLₙ) may include a gate electrode line (170). That is, the gate electrode line 170 may extend in the second direction (D2) on the active region 112 and the device isolation layer 124. The gate electrode line 170 may include material of which a work function is greater than about 4 eV, as disclosed, for example in U.S. Pat. No. 7,253,467. For instance, the gate electrode line 170 may include at least one of titanium nitride (TiN), titanium silicon nitride (TiSiN), tantalum (Ta), tantalum nitride (TaN), tungsten (W), tungsten nitride (WN), hafnium nitride (HfN) and tantalum silicon nitride (TaSiN).

A first gate insulating layer 140, a middle insulating layer 150 and a second gate insulating layer 160 may be sequentially disposed between the gate electrode line 170 and the active region 112 and between the gate electrode line 170 and the device isolation layer 124. The first gate insulating layer 140, the middle insulating layer 150, the second gate insulating 160 and the gate electrode line 170 may be formed along a profile of the active region 112 and the device isolation layer 124. For instance, the first gate insulating layer 140 may be a layer formed by an oxidation process, an atomic layer deposition (ALD) or a chemical vapor deposition (CVD). The middle insulating layer 150 may be formed of a high dielectric material. For instance, the middle insulating layer 150 may include at least one of a silicon nitride layer, a metal oxide layer, a material layer including silicon dot and a material layer including metal dot. The middle insulating layer 150 may be a layer formed by an atomic layer deposition (ALD) or a chemical vapor deposition (CVD). The middle insulating layer 150 may include a charge trap layer 152 which is disposed between the active region 112 and the second gate insulating layer 160 and stores a charge. A charge may be selectively stored in the charge trap layer 152. The second gate insulating layer 160 may include a high dielectric material. For instance, the second gate insulating layer 160 may include at least one of a silicon oxide, a silicon oxynitride and a metal oxide. The first gate insulating layer 140, the middle insulating layer 150 and the second gate insulating layer 160 may extend at least between the gate electrode line 170 and the substrate 110.

A height of a bottom surface of the gate electrode line 170 disposed on the device isolation layer 124 may be different from that of the gate electrode line 170 disposed on the active region 112. For instance, a bottom surface of the gate electrode line 170 disposed on the device isolation layer 124 may be lower than a top surface of the charge trap layer 152 disposed on the active region 112. At the same time, a bottom surface of the gate electrode line 170 disposed on the device isolation layer 124 may be even with the active region 112 or may be higher than the active region 112. If the bottom surface of the gate electrode line 170 disposed on the device isolation layer 124 becomes lower than the active region 112, interference between adjacent word lines may increase because facing areas of the charge trap layers between adjacent word lines excessively increase. The bottom surface of the gate electrode line 170 disposed on the device isolation layer 124 may be even with or lower than a bottom surface of the charge trap layer 152 disposed on the active region. At the same time, the bottom surface of the gate electrode line 170 disposed on the device isolation layer 124 may be even with or higher than the active region 112. The gate electrode line 170 disposed on the device isolation layer 124 may isolate the charge trap layers 152 disposed on the active regions 112.

A bit line (BL) spaced apart from the gate electrode line 170 by an insulating interlayer 180 may extend in the first direction (D1) above the substrate 110. The active region 112 and the bit line (BL) may be electrically connected to each other through the contact (DC).

Referring to FIGS. 1, 3 and 4, a flash memory device according to a second embodiment of the present invention will be described.

A substrate 110 is provided. The substrate 110 may be a silicon wafer or a silicon on insulator (SOI) substrate. A device isolation layer 124 may be disposed in a trench 114 formed in the substrate 110. An active region (ACT) 112 extending in a first direction (DI) may be defined by the device isolation layer 124. A top surface of the device isolation layer 124 may be higher than a top surface of the active region 112. The active region 112 adjacent to the device isolation layer 124 may have a rounded corner 116. For instance, the active region 112 may have a larger radius of curvature at center 117 than at corner 116 (FIG. 4). A plurality of word lines (WL₁, WL₂, . . . WLₙ₋₁, WLₙ) may extend in a second direction (D2) crossing the first direction (D1). A string selection line (SSL), a ground selection line (GSL) and a common source line (CSL) may be disposed in parallel to the word lines (WL₁, WL₂, . . . WLₙ₋₁, WLₙ). The string selection line (SSL) may be disposed to be adjacent to the n'th word line (WLₙ). The ground selection line (GSL) and the common source line (CSL) may be sequentially disposed to be adjacent to the first word line (WL₁).

Each of the word lines (WL₁, WL₂, . . . WLₙ₋₁, Wₙ,) may include a gate electrode line 170. That is, the gate electrode line 170 may extend in the second direction (D2) on the active region 112 and the device isolation layer 124. The gate electrode line 170 may include material of which a work function is greater than about 4 eV. This is respectively disclosed in U.S. Pat. No. 7,253,467. For instance, the gate electrode line 170 may include at least one of titanium nitride (TiN), titanium silicon nitride (TiSiN), tantalum (Ta), tantalum nitride (TaN), tungsten (W),tungsten nitride (WN), hafnium nitride (HfN) and tantalum silicon nitride (TaSiN). A first gate insulating pattern 142, a charge trap layer 152 and a second gate insulating pattern 162 may be sequentially disposed between the gate electrode line 170 and the active region 112. For instance, the first gate insulating pattern 142 may include material formed by an oxidation process, an atomic layer deposition or a chemical vapor deposition. The charge trap layer 152 may be a charge storage layer and include a high dielectric material. For instance, the charge trap layer 152 may include at least one of a silicon nitride layer, a metal oxide layer, a material layer including silicon dot and a material layer including metal dot. The charge trap layer 152 may include material formed by a atomic layer deposition (ALD) or a chemical vapor deposition (CVD). The second gate insulating pattern 162 may include a high dielectric material. For instance, the second gate insulating pattern 162 may include at least one of a silicon oxide, a silicon oxynitride and a metal oxide.

The first gate insulating pattern 142, the charge trap layer 152 and the second gate insulating pattern 162 may be divided on the device isolation layer 124. All the sides of the second gate insulating pattern 162 may be exposed and all or a portion of the charge trap layer 152 may be exposed. An insulating spacer 166 may be disposed on the exposed sides of the charge trap layer 152 and the second gate insulating pattern 162 continuously.

The gate electrode line 170 may extend in the second direction (D2) and may be disposed between the adjacent insulating spacers 166. For instance, a bottom surface of the gate electrode line 170 disposed on the device isolation layer 124 may be lower than a top surface of the charge trap layer 152 disposed on the active region 112. At the same time, a bottom surface of the gate electrode line 170 disposed on the device isolation layer 124 may be even with or higher than the active region 112. A bottom surface of the gate electrode line 170 disposed on the device isolation layer 124 may be even with or lower than a bottom surface of the charge trap layer 152 disposed on the active region 112. At the same time, a bottom surface of the gate electrode line 170 disposed on the device isolation layer 124 may be even with or higher than the active region 112. The gate electrode line 170 disposed on the device isolation layer 124 may isolate the charge trap layers 152 on the active region 112.

A bit line (BL) which is spaced apart from the gate electrode line 170 by an insulating interlayer 180 may extend in the first direction (D1) above the substrate 110. The active region 112 and the bit line (BL) may be electrically connected to each other through the contact (DC).

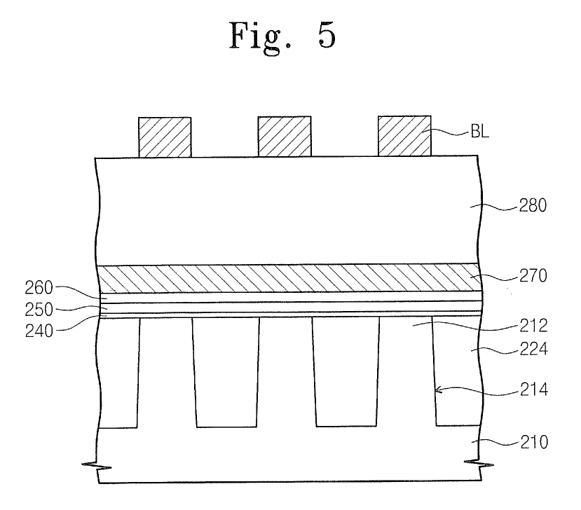

Referring to FIGS. 1 and 5, a comparative example for comparing a characteristic with a first embodiment of the present invention will be described.

A substrate 210 is provided. A device isolation layer 224 may be disposed in the substrate 210. An active region (ACT) 212 extending in a first direction (DI) may be defined by the device isolation layer 224. A top surface of the device isolation layer 224 may be even with or higher than a top surface of the substrate 210. A plurality of word lines (WLₙ, WL₂, . . . WLₙ₋₁, WLₙ) may extend in a second direction (D2) crossing the first direction (D1). A string selection line (SSL), a ground selection line (GSL) and a common source line (CSL) may be disposed in parallel to the word lines (WL₁, WL₂, . . . WLₙ₋₁, WLₙ). The string selection line (SSL) may be disposed to be adjacent to the n'th word line (WLₙ). The ground selection line (GSL) and the common source line (CSL) may be sequentially disposed to be adjacent to the first word line (WL₁).

Each of the word lines (WL₁, WL₂, . . . WLₙ₋₁, WLₙ) may include a gate electrode line (270). That is, the gate electrode line 270 may extend in the second direction (D2) on the active region 212 and the device isolation layer 224. The gate electrode line 270 may include material of which a work function is greater than about 4 eV. A first gate insulating layer 240, a middle insulating layer 250 and a second gate insulating layer 260 may be sequentially disposed between the gate electrode line 270 and the active region 212 and between the gate electrode line 270 and the device isolation layer 224. The first gate insulating layer 240, the middle insulating layer 250, the second gate insulating 260 and the gate electrode line 270 may be formed to be parallel to a top surface of the substrate 210. That is, a bottom surface of the gate electrode line 270 may be almost the same height on the device isolation layer 224 and on the active region 212. The first gate insulating layer 240 may include a silicon oxide formed by an oxidation process. The middle insulating layer 250 is a charge storage layer and may include a silicon nitride layer. The second gate insulating layer 260 may include a silicon oxide. The first gate insulating layer 240, the middle insulating layer 250 and the second gate insulating layer 260 may extend onto the substrate 210.

A bit line (BL) which is spaced apart from the gate electrode line 270 by an insulating interlayer 280 may extend in the first direction (D1) above the substrate 210. The active region 212 and the bit line (BL) may be electrically connected to each other through the contact (DC).

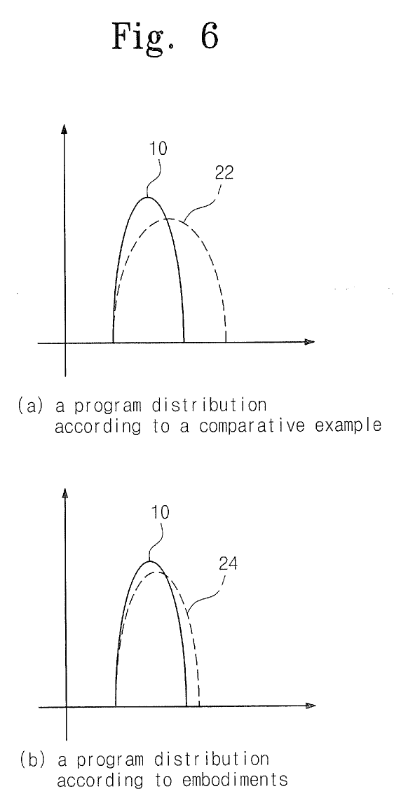

Referring to FIGS. 1 and 6, a characteristic of a flash memory device according to some embodiments and a comparative example of the present invention will be described. In one selected word line (WLₙ₋₁), a program characteristic of an even numbered memory cell and an odd numbered memory cell will be described.

In embodiments and a comparative example, a program operation is performed to a selected word line (WLₙ₋₁) and an even numbered memory cell disposed on a selected bit line (BLₙ). A program voltage (V_{pgam}) (e.g. about 18V) is applied to the selected word line (WLₙ₋₁) and a pass voltage (Vₚₐₛₛ) (e.g. about 5V) is applied to a nonselective word line. At this time, a voltage of 0V is applied to a bulk (e.g., a well region) in which memory cell are formed. A ground voltage is applied to the selected bit line (BLₙ) to program a memory cell, while a supply voltage (Vcc) is applied to a nonselected bit line to inhibit a program. A supply voltage (Vcc) is applied to a string selection line (SSL) and a voltage of 0V is applied to a ground selection line (GSL). A voltage of 1.2V may be applied to a common source line (CSL). A first distribution 10 of a threshold voltage of an even numbered cell which is programmed as stated above is measured. The first distributions 10 of the threshold voltage of embodiments and a comparative example represent almost the same distribution.

In embodiments and a comparative example, a program operation is performed first on an odd numbered memory cell disposed on a selected word line (WLₙ₋₁) and a selected bit line (BLₙ₋₁) using a method of the above statement. After that, a program operation is applied to an even numbered memory cell disposed on a selected word line (WLₙ₋₁) and a selected bit line (BLₙ) using a method of the-above statement. Second Distributions 22 and 24 of a threshold voltage of even numbered memory cell adjacent to a programmed odd numbered memory cell are measured. In a comparative example, the second distribution 22 of the threshold voltage of even numbered memory cell represents a threshold voltage change of 50% or more according to program or non-program of odd numbered memory cell. In embodiments, a second distribution of a threshold voltage of even numbered memory cell represents a similar distribution regardless of program or non-program of odd numbered memory cell. Since charge trap layers 152 in embodiments may be isolated from each other by a gate electrode pattern 170, interference does not occur when adjacent memory cell is programmed.

Referring to FIGS. 1, 2 and 7 through 10, a method of forming a flash memory device according to a first embodiment of the present invention will be described.

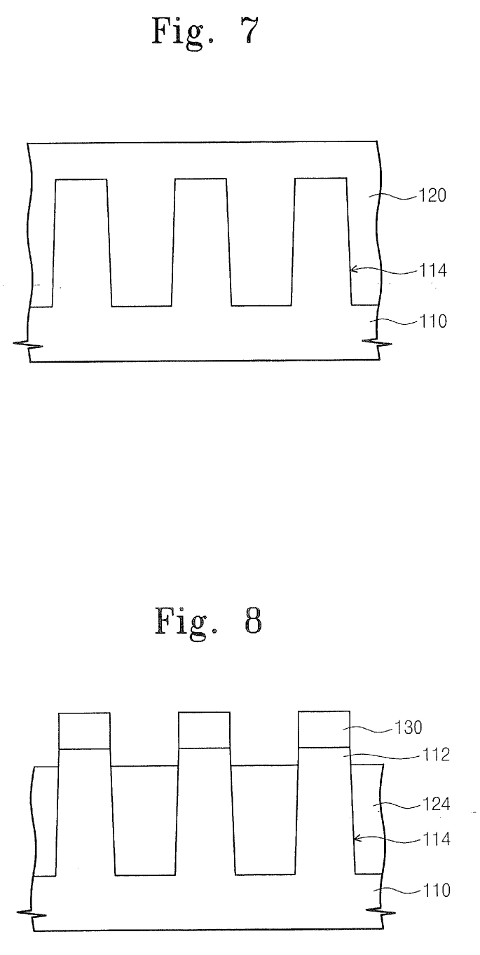

Referring to FIG. 7, a substrate 110 is provided. The substrate 110 may be a silicon wafer or a silicon on insulator (SOI) substrate. A trench 114 may be formed in the substrate 110. For instance, the trench 114 may be formed by an etching process using a mask pattern (not shown). A trench insulating layer 120 may be formed on the substrate 110 to fill the trench 114.

Referring to FIG. 8, a portion of the trench insulating layer 120 is removed to form device isolation layers 124 isolated in the trench 114. An active region 112 extending in a first direction (D1) may be defined by the device isolation layer 124. A sacrifice pattern 130 selectively exposing the device isolation layer 124 may be formed on the active region 112. The sacrifice pattern may include material having an etching selectivity with respect to the active region 112 and the device isolation layer 124. For instance, the sacrifice pattern 130 may include a silicon nitride layer and/or a silicon oxynitride layer. The device isolation layer 124 may be formed by an etching process. The trench insulating layer 120 may be recessed by the etching process so that a top surface of the device isolation layer 124 is lower than a top surface of the active region 112. The device isolation layer 124 may be formed by a planarization process and a recess process. The planarization process may be an etched back process or a chemical mechanical polishing process. A portion of the trench insulating layer 120 may be removed by the planarization process so as to expose a top surface of the active region 112. The sacrifice pattern 130 may be formed on a top surface of the exposed active region 112. Subsequently, a recess process may be performed so that the device isolation layer 124 lower than a top surface of the active region 112 is formed.

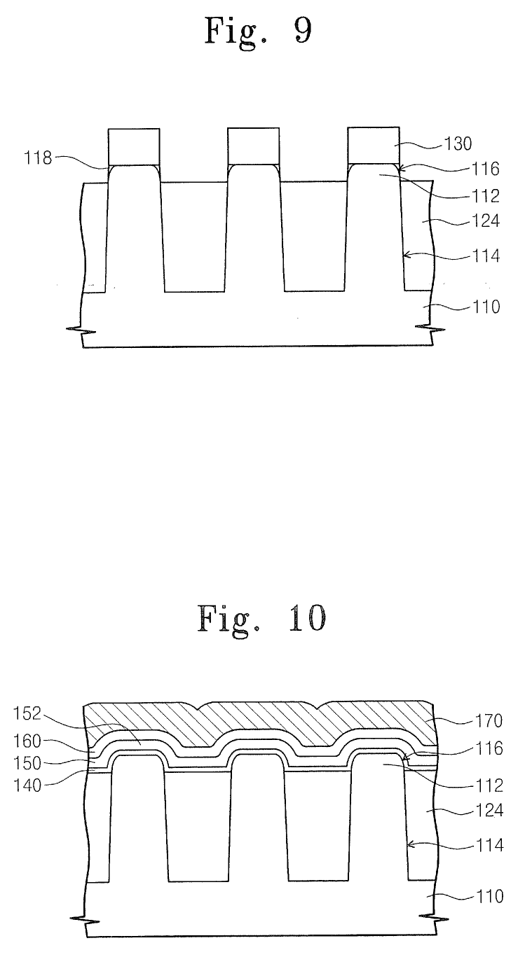

Referring to FIG. 9, an oxidation process may be applied to a corner of the active region 112 exposed by the device isolation layer 124. The exposed corner may be oxidized by the oxidation process to form bird's beak 118. A top surface of the active region 112 may be protected from an oxidation process by the sacrifice pattern 130. Thus, the active region 112 may have a rounded corner 116 exposed on a side of the trench 114.

Referring to FIG. 10, the sacrifice pattern 130 may be removed. The sacrifice pattern 130 may have a higher etching selectivity than the device isolation layer 124 and the active region 112. The bird's beak 118 and the sacrifice pattern 130 may be simultaneously removed. A first gate insulating layer 140 may be formed on the exposed active region 112. When the bird's beak 118 remains, the first gate insulating layer 140 may include the bird's beak 118. The first gate insulating layer 140 may be conformally formed by an oxidation process. The first gate insulating layer 140 may be formed by an atomic layer deposition (ALD) process or a chemical vapor deposition (CVD) process.

A middle insulating layer 150 may be formed on the first gate insulating layer 140. The middle insulating layer 150 may be conformally formed, and may include a high dielectric material layer. For instance, the middle insulating layer 150 may include at least one of a metal oxide layer, a silicon nitride layer, a material layer including silicon dot and a material layer including metal dot. The middle insulating layer 150 may be formed by an atomic layer deposition (ALD) process or a chemical vapor deposition (CVD) process. The middle insulating layer 150 may include a charge trap layer 152, which stores data by trapping a charge, on the active region 112.

A second gate insulating layer 160 may be formed on the middle insulating layer 150. The second insulating layer 160 may be conformally formed and may include a high dielectric material. For instance, the second gate insulating layer 160 may include at least one of a silicon oxide, a silicon oxynitride and a metal oxide.

A conductive layer (not shown) may be formed on the second gate insulating layer 160. The conductive material may include material of which a work function is greater than about 4 eV. This is respectively disclosed in U.S. Pat. No. 7,253,467. The conductive layer may include at least one of titanium nitride (TiN), titanium silicon nitride (TiSiN), tantalum (Ta), tantalum nitride (TaN), tungsten (W), tungsten nitride (WN), hafnium nitride (HfN) and tantalum silicon nitride (TaSiN). The conductive layer is patterned in a second direction (D2) crossing the first direction (D1) to form a gate electrode line 170. A bottom surface of the gate electrode line 170 may extend in the second direction (D2) along a surface profile of the device isolation layer 124 and the active region 112. A height of a bottom surface of the gate electrode line 170 disposed on the device isolation layer 124 may be different from that of the gate electrode line 170 disposed on the active region 112. A bottom surface of the gate electrode line 170 disposed on the device isolation layer 124 may be lower than a top surface of the charge trap layer 152 disposed on the active region 112. At the same time, a bottom surface of the gate electrode line 170 disposed on the device isolation layer 124 may be even with or higher than the active region 112. A bottom surface of the gate electrode line 170 disposed on the device isolation layer 124 may be even with or lower than a bottom surface of the charge trap layer 152 disposed on the active region 112. At the same time, a bottom surface of the gate electrode line 170 disposed on the device isolation layer 124 may be even with or higher than the active region 112.

Referring to FIGS. 10 and 2, an insulating interlayer 180 may be formed on the resultant structure. A bit line (BL) extending in the first direction may be formed on the insulating interlayer 180.

Referring to FIGS. 1, 3 and 11 through 16, a method of forming a flash memory device according to second embodiment of the present invention will be described.

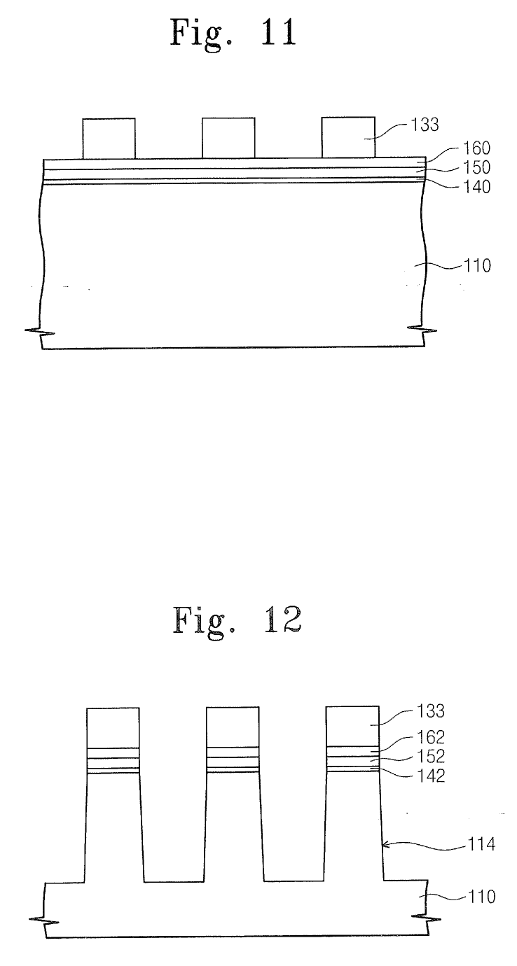

Referring to FIG. 11, a substrate 110 is provided. The substrate 110 may be a silicon wafer or a silicon on insulator (SOI). A first gate insulating layer 140 may be formed on the exposed substrate 110. The first gate insulating layer 140 may be conformally formed by an oxidation process. The first gate insulating layer 140 may be formed by an atomic layer deposition (ALD) process or a chemical vapor deposition (CVD) process.

A middle insulating layer 150 may be formed on the first gate insulating layer 140. The middle insulating layer 150 may be conformally formed, and may include a high dielectric material layer. The middle insulating layer 150 may include at least one of a silicon nitride layer, a metal oxide layer, a material layer including metal dot and a material layer including silicon dot. The middle insulating layer 150 may be formed by an atomic layer deposition (ALD) process or a chemical vapor deposition (CVD) process.

A second gate insulating layer 160 may be formed on the middle insulating layer 150. The second gate insulating layer 160 may be conformally formed, and may include a high dielectric material layer. The second gate insulating layer 160 may include at least one of a silicon oxide, a silicon oxynitride and a metal oxide.

A mask pattern 133 may be formed on the second gate insulating layer 160. The mask pattern 133 may include a photoresist layer and/or a silicon nitride layer.

Referring to FIG. 12, the second gate insulating layer 160, the middle insulating layer 150, the first gate insulating layer 140 and the substrate 110 that are exposed by the mask pattern 133 may be sequentially etched using the mask pattern 133 as an etching mask. As a result, a trench 114 is formed in the substrate 110 and a first gate insulating pattern 142, a charge trap layer 152 and a second gate insulating pattern 162 may be formed.

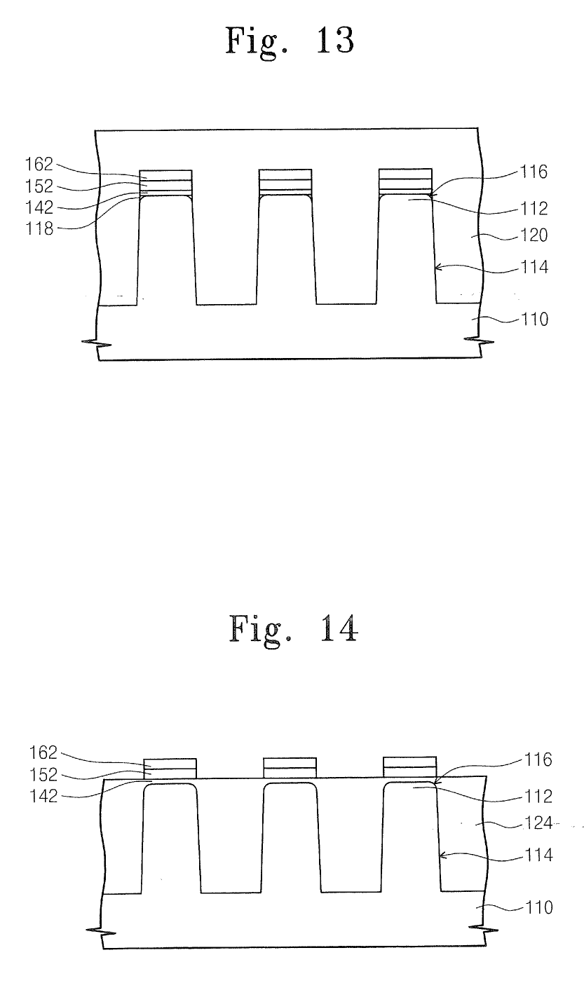

Referring to FIG. 13, an oxidation process may be applied to an inner wall of the trench 114. The inner wall of the trench 114 damaged during an etching process may be cured by the oxidation process. A bird's beak may be formed on a corner of an active region 112 by the oxidation process. That is, the active region 112 may have a rounded corner 116 on a region which is exposed to the inner wall of the trench 114 and is adjacent to the first gate insulating pattern 142.

The mask pattern 133 may be selectively removed. A trench insulating layer 120 may be formed on the substrate 110 to fill the trench 114. The bird's beak 118 and the mask pattern 133 may be simultaneously removed. When the bird's beak remains, the bird's beak is a part of the trench insulating layer.

Referring to FIG. 14, a portion of the trench insulating layer 120 is removed to form device isolation layers 124 isolated in the trench 114. The active region 112 may be defined by the device isolation layer 124. The active region 112 may extend in a first direction (D1) and have a rounded corner 116. The device isolation layer 124 may be formed by an etching process. The etching process is performed to expose a top surface and a side surface of the second gate insulating pattern 162 while the etching process may be performed so that a top surface of the device isolation layer 124 is not lower than a top surface of the active region A 112. The etching process may expose all or a portion of a side surface of the second gate insulating pattern 162.

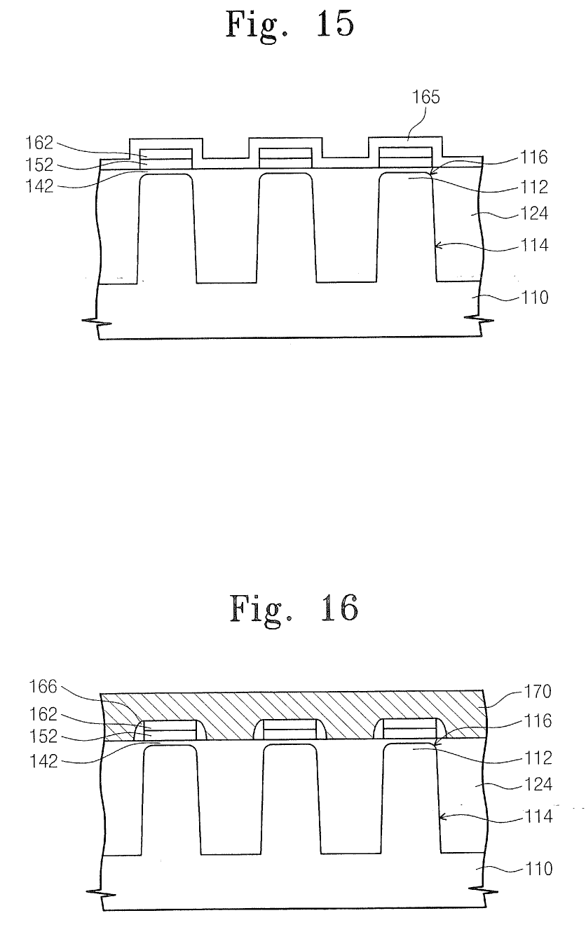

Referring to FIG. 15, a spacer layer 165 may be conformally formed on a resultant structure. The spacer layer 165 may be formed to have a same thickness on a top surface of the second gate insulating pattern 162 and a top surface of the device isolation 124. The spacer layer 165 may include an insulating material that may be the same material as the device isolation layer 124.

Referring to FIG. 16, the spacer layer 165 may be anisotropically etched to form an insulating spacer 166. The insulating spacer 166 may be continuously formed on a side of the exposed second gate insulating pattern 162 and a side of the exposed charge trap layer 152.

A conductive layer (not shown) may be formed on the second gate insulating pattern 162, the insulating spacer 166 and the device isolation layer 124. The conductive layer may be formed to fill a space between the insulating patterns 152 and 162. The conductive layer may include material of which a work function is greater than about 4 eV. This is respectively disclosed in U.S. Pat. No. 7,253,467. The conductive layer may include at least one of titanium nitride (TiN), titanium silicon nitride (TiSiN), tantalum (Ta), tantalum nitride (TaN), tungsten (W), tungsten nitride (WN), hafnium nitride (HfN) and tantalum silicon nitride (TaSiN). The conductive layer may be patterned in a second direction (D2) crossing the first direction (D1) to form a gate electrode line 170. The gate electrode line 170 may extend in the second direction (D2) and may be interposed between adjacent insulating spacers 166. For instance, a bottom surface of the gate electrode line 170 disposed on the device isolation layer 124 may be lower than a top surface of the charge trap layer 152 disposed on the active region 112. At the same time, a bottom surface of the gate electrode line 170 disposed on the device isolation layer 124 may be even with the active region 112 or may be higher than the active region 112. A bottom surface of the gate electrode line 170 disposed on the device isolation layer 124 may be even with or lower than a bottom surface of the charge trap layer 152 disposed on the active region. At the same time, a bottom surface of the gate electrode line 170 disposed on the device isolation layer 124 may be even with or higher than the active region 112.

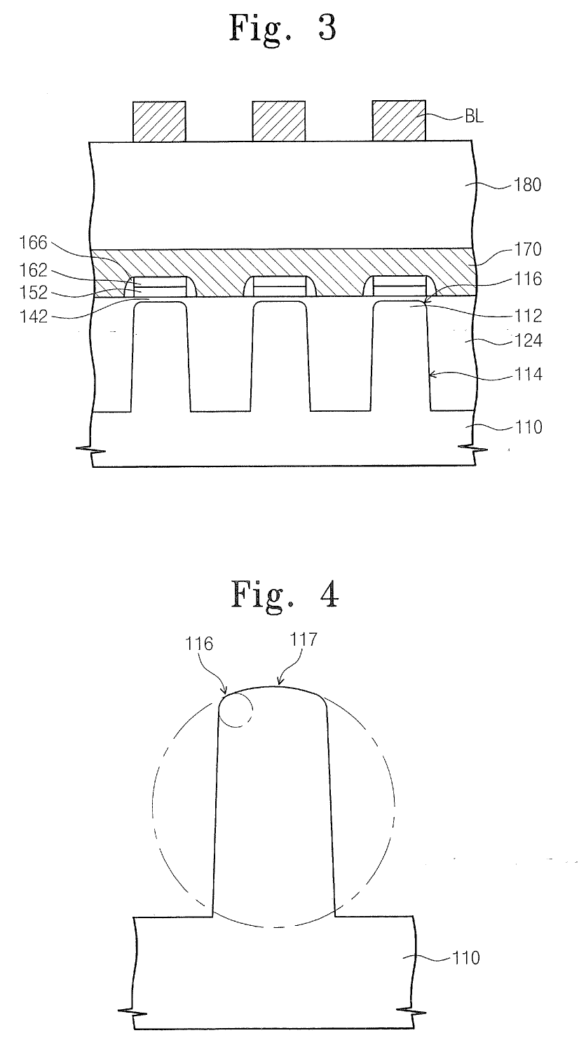

Referring to FIGS. 16 and 3 again, an insulating interlayer 180 may be formed on a resultant structure. A bit line (BL) extending in the first direction (D1) may be formed on the insulating interlayer 180.

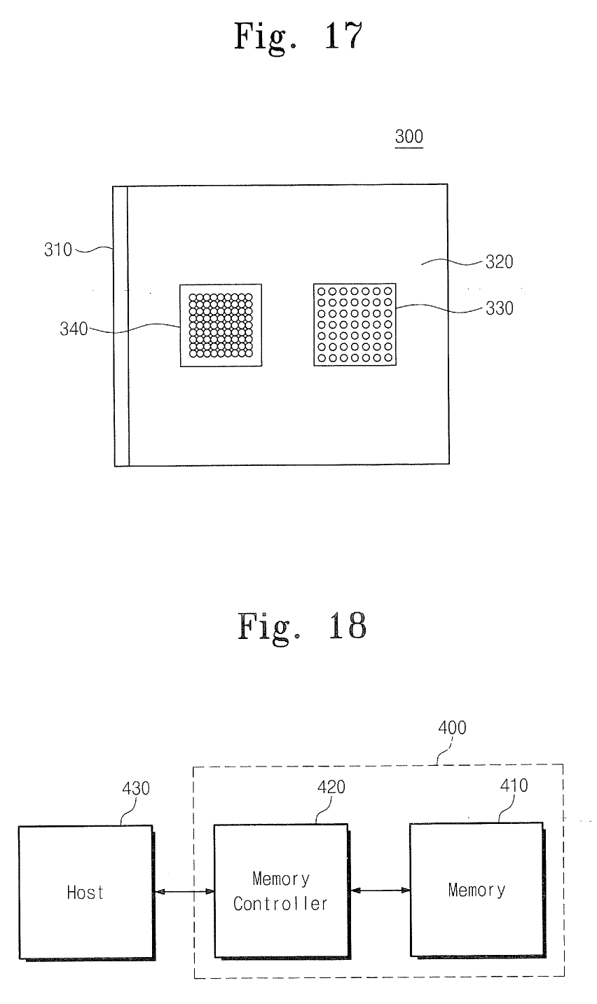

Referring to FIG. 17, a memory device module including a flash memory device according to an embodiment of the present invention will be described.

A memory device module 300 may include a printed circuit board 320. The printed circuit board 320 may be one of external surfaces of the memory device module 300. The printed circuit board 320 may support a memory unit 330, a device interface unit 340 and an electrical connector 310.

The memory unit 330 may include a three dimensional memory array and may be connected to a memory array controller. The memory array may include a plurality of memory cells arranged in a three dimensional lattice on the board. The memory cells may be flash memory cells according to embodiments of the present invention.

The device interface unit 340 is formed on a divided board and may be electrically connected to the memory unit 330 and the connector 310 by the printed circuit board 320. The memory unit 330 and the device interface unit 340 may be directly mounted on the printed circuit board 320. The device interface unit 340 may include elements which are needed to generate a voltage, a clock frequency and protocol logic.

Referring to FIG. 18, a memory system including a flash memory device according to embodiments of the present invention will be described.

A memory system 400 may include a memory device 410 for storing huge amounts of data and a memory controller 420. The memory device 410 may be a flash memory device according to embodiments of the present invention. The memory controller 420 controls the memory device 410 so as to read data stored in the memory device 410 or to write data into the memory device 410 in response to a request of read/write of a host 430. The memory controller 420 may constitute an address mapping table for mapping an address provided from the host 430 (a mobile device or a computer system) into a physical address of the memory device 410.

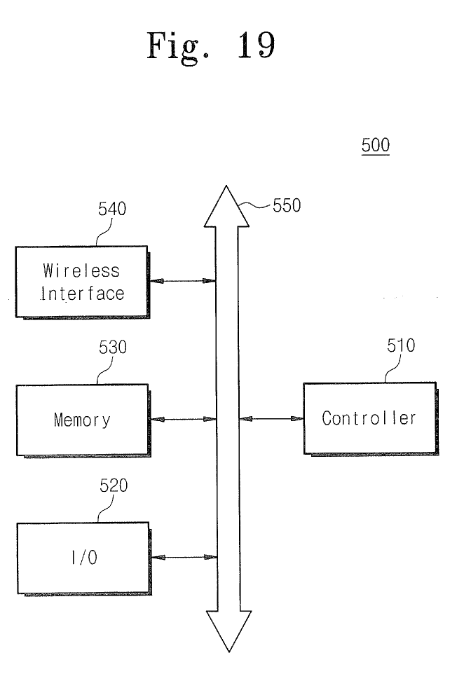

Referring to FIG. 19, an electronic device 500 including a flash memory device according to embodiments of the present invention will be described. The electronic device 500 may be used in a wireless communication device such as PDA, a laptop computer, a mobile computer, a web tablet, a wireless phone, a cell phone, a digital music player or in all devices that can transmit and receive data in a wireless environment.

The electronic device 500 may include a controller 510, a memory 530, a wireless interface 540 and input/output devices 520 such as, a keypad, a keyboard, a display that are combined to each other through a bus 550. The controller 510 may include microprocessors which are one or more, a digital signal process, a microcontroller or the like. The memory 530 may be used to store a user data. The memory 530 includes a flash memory device according to embodiments of the present invention.

The electronic device 500 may use a wireless interface 540 to transmit data to a wireless communication network communicating using a RF signal or to receive data from network. The wireless interface 540 may include a antenna, a wireless transceiver and so on.

The electronic system 500 may be used in a communication interface protocol of a third generation communication system such as CDMA, GSM, NADC, E-TDMA, WCDMA, CDMA2000.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

1. A flash memory device, comprising:
a gate electrode line which extends in a second direction crossing a first direction on a substrate including an active region which is defined by a device isolation layer and extends in the first direction; and
a charge trap layer disposed between the active region and the gate electrode line, wherein a bottom surface of the gate electrode line disposed on the device isolation layer is lower than a top surface of the charge trap layer disposed on the active region and higher than a top surface of the active region.

2. The flash memory device of claim 1, wherein a corner of the active region in contact with the device isolation layer is rounded.

3. The flash memory device of claim 1, wherein a top surface of the device isolation layer is further recessed than top surface of the active region.

4. The flash memory device of claim 1, wherein the charge trap layer includes at least one of a silicon nitride layer, a silicon oxynitride layer, a material layer including silicon dot, a material layer including metal dot and a metal oxide layer.

5. The flash memory device of claim 1, wherein the gate electrode line includes a material of which a work function is greater than 4 eV.

6. The flash memory device of claim 5, wherein the gate electrode line includes at least one of titanium nitride, titanium silicon nitride, tantalum, tantalum nitride, tungsten nitride, tungsten, hafnium nitride and tantalum silicon nitride.

7. The flash memory device of claim 1, further comprising:
a first insulating layer interposed between the active region and the charge trap layer; and
a second insulating layer interposed between the charge trap layer and the gate electrode line.

8. The flash memory device of claim 7, wherein the second insulating layer includes at least one of a silicon nitride, a silicon oxynitride and a metal oxide.

9. The flash memory device of claim 7, wherein at least one of the first and second insulating layers extends between the gate electrode line and the substrate.

10. The flash memory device of claim 1, wherein the charge trap layer extends between the gate electrode line and the substrate.

11. The flash memory device of claim 1, wherein the charge trap layer is cut on the device isolation layer.

12. The flash memory device of claim 11, further comprising an insulating spacer on a sidewall of the charge trap layer.

13.-20. (canceled)
